(19) United States
(12) Patent Application Publication
(10) Pub. No.: US 2026/0107742 A1
(43) Pub. Date: Apr. 16, 2026

(54) SUBSTRATE PROCESSING APPARATUS

(71) Applicant: Samsung Electronics Co., Ltd., Suwon-si (KR)

(72) Inventors: Sangjine PARK, Suwon-si (KR); Ji Hwan PARK, Suwon-si (KR)

(73) Assignee: Samsung Electronics Co., Ltd., Suwon-si (KR)

(21) Appl. No.: 19/179,190

(22) Filed: Apr. 15, 2025

(30) Foreign Application Priority Data
Oct. 11, 2024 (KR) 10-2024-0138847

(51) Int. Cl. H01L 21/687; H01L 21/67

(52) U.S. Cl. CPC H10P 72/7618; H10P 72/0424; H10P 72/7612

(57) ABSTRACT

A substrate processing apparatus may include a spin chuck, a process fluid supplied, and a negative pressure generator. The spin chuck may include a flat portion having a flat upper surface and a recess portion surrounded by the flat portion in a plan view, the recess portion having a recess upper surface, the spin chuck including a first inlet in the recess upper surface of the recess portion, the recess upper surface of the recess portion at a lower level than the flat upper surface of the flat portion. The process fluid supplier is configured to supply a process fluid onto a substrate loaded on the spin chuck. The negative pressure generator is configured to provide a first negative pressure through the first inlet in the recess upper surface of the recess portion.

### CROSS-REFERENCE TO RELATED APPLICATION(S)

This U.S. non-provisional application claims priority under 35 USC § 119 to Korean Patent Application No. 10-2024-0138847, filed on Oct. 11, 2024, in the Korean Intellectual Property Office, the disclosure of which is herein incorporated by reference in its entirety.

### BACKGROUND

The present inventive concepts relate to substrate processing apparatuses and, more specifically, to substrate processing apparatuses including a spin chuck that supports a substrate.

Semiconductor devices can be manufactured by various manufacturing processes. In a wet etching process among these manufacturing processes, a substrate may be etched by a water-soluble chemical, an organic solvent, or a mixture thereof. As the level of integration of semiconductors is improved, the importance of precisely controlling the wet etching process is increasing.

### SUMMARY

The present inventive concepts may be directed to providing a substrate processing device capable of selectively etching an edge of a substrate. Such a substrate processing device may be configured to support wet etching equipment configured perform a more effective wet etching process in the mass production of semiconductor devices.

The present inventive concepts may also be directed to providing a substrate processing device capable of reducing or minimizing the phenomenon in which a diameter of a substrate decreases after an etching process.

The present inventive concepts may also be directed to providing a substrate processing device capable of controlling the movement of a process fluid.

The present inventive concepts may be directed to providing a substrate processing device capable of deforming a substrate.

The present inventive concepts may also be directed to providing a substrate processing device in which performance in fixing a substrate is improved.

The present inventive concepts may also be directed to providing a substrate processing device capable of securing the stability of a process.

A substrate processing apparatus according to some example embodiments of the present inventive concepts may include a spin chuck, a process fluid supplied, and a negative pressure generator. The spin chuck may include a flat portion having a flat upper surface and a recess portion surrounded by the flat portion in a plan view, the recess portion having a recess upper surface, the spin chuck including a first inlet in the recess upper surface of the recess portion, the recess upper surface of the recess portion at a lower level than the flat upper surface of the flat portion. The process fluid supplier is configured to supply a process fluid onto a substrate loaded on the spin chuck. The negative pressure generator is configured to provide a first negative pressure through the first inlet in the recess upper surface of the recess portion.

A substrate processing apparatus according to some example embodiments of the present inventive concepts may include a spin chuck, a process fluid supplied, and a negative pressure generator. The spin chuck may include a flat portion having a flat upper surface and a recess portion surrounded by the flat portion in a plan view, the recess portion having a recess upper surface, the spin chuck including a first inlet in the recess upper surface of the recess portion, the spin chuck including a second inlet in the flat upper surface of the flat portion, a level of the recess upper surface of the recess portion decreasing toward a center of the spin chuck. The process fluid supplier may be configured to supply an etchant onto a substrate loaded on the spin chuck. The negative pressure generator may be configured to provide a first negative pressure through the first inlet in the recess upper surface of the recess portion, and provide a second negative pressure through the second inlet in the flat upper surface of the flat portion.

A substrate processing apparatus according to some example embodiments of the present inventive concepts may include a spin chuck, a process fluid supplier, a negative pressure generator, and support pins. The spin chuck may include a flat portion having a flat upper surface and a recess portion surrounded by the flat portion in a plan view, the recess portion having a recess upper surface, the spin chuck including a first inlet in the recess upper surface of the recess portion, a level of the recess upper surface of the recess portion decreasing toward a center of the spin chuck. The process fluid supplier may be configured to supply an etchant onto a substrate loaded on the spin chuck. The negative pressure generator may be configured to provide a first negative pressure through the first inlet in the recess upper surface of the recess portion. The support pins may be configured to at least partially extend through separate, respective support holes defined in the flat portion. The support pins may be vertically movable.

According to some example embodiments, an operation method of a substrate processing may include loading a substrate on a spin chuck. The spin chuck may include a flat portion having a flat upper surface and a recess portion surrounded by the flat portion in a plan view, the recess portion having a recess upper surface, the spin chuck including a first inlet in the recess upper surface of the recess portion, the recess upper surface of the recess portion at a lower level than the flat upper surface of the flat portion. The operation method may include applying a first negative pressure to the substrate through the first inlet to deform at least a portion of the substrate into a concave shape based on drawing the portion of the substrate into contact with the recess upper surface of the recess portion. The portion of the substrate may be drawn into contact with the recess upper surface based on exposing a bottom surface of the portion of the substrate to the first negative pressure provided through the first inlet. The operation method may include supplying a process fluid onto the substrate concurrently with the substrate having the concave shape, such that at least a portion of the process fluid is contained on a concave surface defined by an upper surface of the substrate while the substrate has the concave shape. The operation method may include at least partially etching at least a portion of the upper surface of the substrate based on rotating the substrate around a central axis at least partially concurrently with the portion of the process fluid being contained on the concave surface.

The operation method may include selectively edging a central portion of the upper surface of the substrate based on the rotation concurrently with the substrate being deformed in the concave shape, such that at least an edge of the substrate is not etched by the process fluid during at least the rotation.

The operation method may include supplying the process fluid from a nozzle and further moving the nozzle in a horizontal direction over the upper surface of the substrate during the supplying of the process flow, the horizontal direction being parallel to the flat upper surface of the flat portion of the spin chuck.

The operation method may include stopping the rotation of the substrate. The operation method may include stopping the application of the first negative pressure to cause the substrate to deform from the concave shape to a rest shape.

The operation method may include stopping the application of the first negative pressure at least partially subsequently to the stopping of the rotation.

The spin chuck may include a second inlet in the flat upper surface of the flat portion, and the operation method may include applying a second negative pressure to the substrate through the second inlet to fix the substrate to at least the flat upper surface of the flat portion of the spin chuck. The applying of the second negative pressure may be performed prior to stopping the application of the first negative pressure. The applying of the second negative pressure may be performed subsequent to the stopping of the rotation.

The supplying of the process fluid onto the substrate and the rotation of the substrate may be performed at least partially concurrently with the second negative pressure being applied to the substrate such that the process fluid may flow toward an edge of the substrate based on centrifugal force. The process fluid may flow from the upper surface of the substrate and over the edge of the substrate towards a bottom surface of the substrate, such that the process fluid etches both the upper surface of the substrate and the edge of the substrate.

The operation method may include directing at least a portion of the process fluid flowing over the edge of the substrate to further flow to an outlet in a central portion of the recess upper surface of the recess portion.

The operation method may include directing the portion of the process fluid to flow to the outlet through a drain groove in an upper surface of the spin chuck.

The operation method may include causing at least a portion of the process fluid flowing over the upper surface of the substrate to flow into an inflow hole according to centrifugal force based on the rotation.

The loading of the substrate onto the spin chuck may include causing respective lift pin tips to protrude from an upper surface of the spin chuck to support the substrate above the upper surface of the spin chuck and causing the lift pin tips to retract into the upper surface of the spin chuck to lower the substrate onto the upper surface of the spin chuck to contact at least the flat upper surface of the flat portion.

The operation method may include supporting at least an outer portion of the substrate spaced apart from the flat portion of the spin chuck based on the substrate having the concave shape, the supporting based on causing at least respective support pin tips to protrude from the flat upper surface of the flat portion to contact a bottom surface of the outer portion of the substrate based on the application of the first negative pressure.

The operation method may include retracting the support pin tips through respective support pin holes in the flat upper surface prior to or subsequently to stopping the application of the first negative pressure. The operation method may include retracting the support pin tips through respective support pin holes in the flat upper surface prior to or subsequently to stopping the rotation.

The operation method may include applying the first negative pressure and applying the second negative pressure asynchronously or synchronously.

The operation method may include applying the second negative pressure and causing the support pins to move vertically asynchronously or synchronously.

### BRIEF DESCRIPTION OF DRAWINGS

FIG. 1 is a view showing a substrate processing apparatus according to some example embodiments of the present inventive concepts.

FIG. 2 is a perspective view of a spin chuck according to some example embodiments of the present inventive concepts.

FIG. 3 is a cross-sectional view taken along line I-I′ of FIG. 2.

FIG. 4 is a cross-sectional view taken along line II-II′ of FIG. 2.

FIG. 5 is a conceptual diagram of a negative pressure generator according to some example embodiments of the present inventive concepts.

FIG. 6 is a perspective view of a spin chuck according to some example embodiments of the present inventive concepts.

FIG. 7 is a flowchart showing an operation method of a substrate processing apparatus according to some example embodiments of the present inventive concepts.

FIGS. 8, 9, 10, 11, 12, 14, and 15 are views showing the operation method of the substrate processing apparatus according to some example embodiments of the present inventive concepts.

FIG. 13 is an enlarged view of region ST1 of FIG. 12 according to some example embodiments of the present inventive concepts.

FIG. 16 is an enlarged view of region ST2 of FIG. 15 according to some example embodiments of the present inventive concepts.

FIG. 17 is a perspective view of a spin chuck according to some example embodiments of the present inventive concepts.

FIG. 18 is a view showing a substrate processing apparatus according to some example embodiments of the present inventive concepts.

FIGS. 19, 20, and 21 are views showing an operation method of a substrate processing apparatus according to some example embodiments of the present inventive concepts.

FIG. 22 is a perspective view showing a spin chuck according to some example embodiments of the present inventive concepts.

### DETAILED DESCRIPTION

Hereafter, example embodiments of the present inventive concepts will be clearly and thoroughly described with reference to the accompanying drawings.

As the inventive concepts allow for various changes and numerous various example embodiments, some example embodiments will be illustrated in the drawings and described in detail in the written description. However, this is not intended to limit the inventive concepts to particular modes of practice, and it is to be appreciated that all modifications, equivalents, and substitutes that do not depart from the spirit and technical scope of the inventive concepts are encompassed in the inventive concepts. In describing the inventive concepts, when it is determined that the specific description of the known related art unnecessarily obscures the gist of the inventive concepts, the detailed description thereof will be omitted.

A portion of an element described as being “on” or “above” another element as used herein, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

In order to clearly explain the present inventive concepts in the drawings, parts that are not related to the description are omitted, and similar parts are given similar reference numerals throughout the specification. In the methods described herein, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

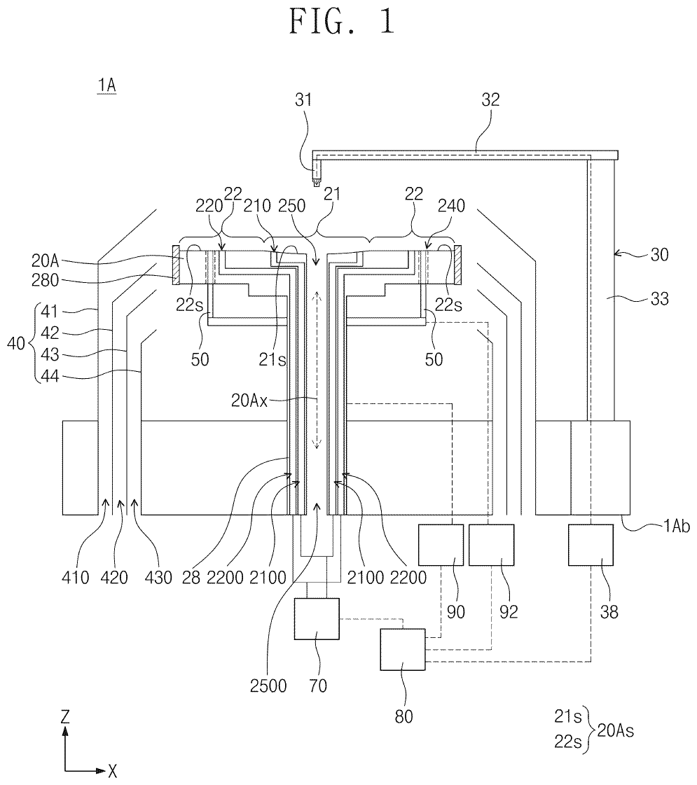

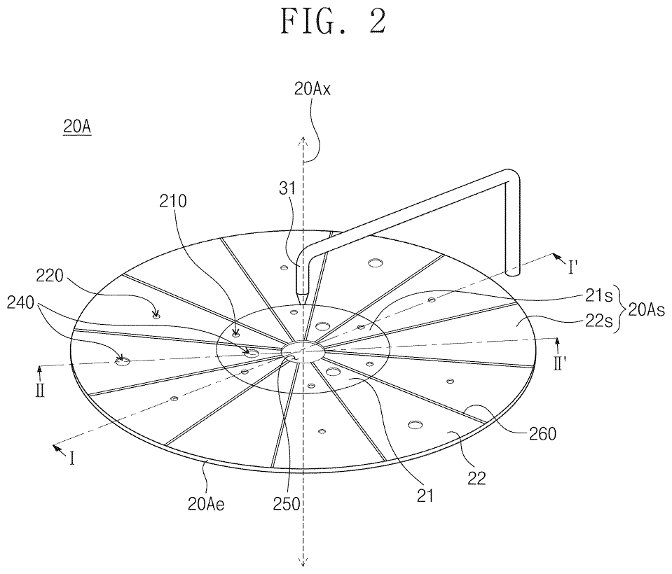

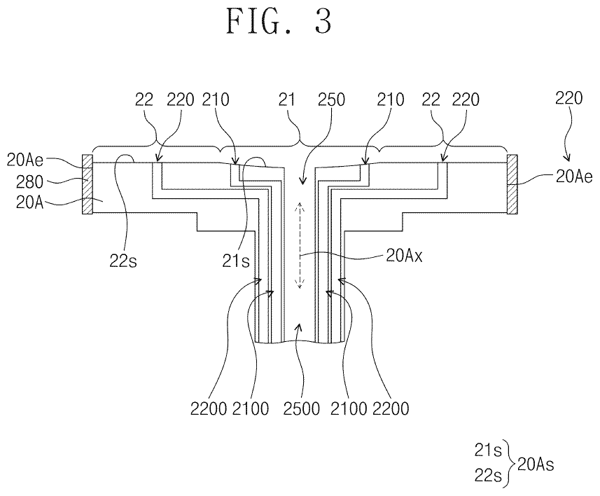

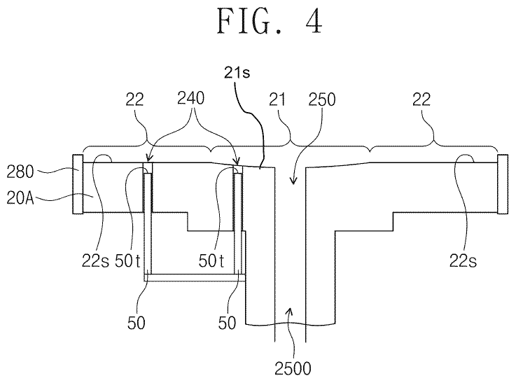

FIG. 1 is a view showing a substrate processing apparatus 1A according to some example embodiments of the present inventive concepts. FIG. 2 is a perspective view of a spin chuck 20A according to some example embodiments of the present inventive concepts. FIG. 3 is a cross-sectional view taken along line I-I′ of FIG. 2. FIG. 4 is a cross-sectional view taken along line II-II′ of FIG. 2.

Referring to FIGS. 1 to 4, the substrate processing apparatus 1A may include a process fluid supplier 30 including a nozzle 31 and a spin chuck 20A provided under the nozzle 31 and set (configured) to support a substrate.

The process fluid supplier 30 may be set (configured) to supply a process fluid onto a substrate loaded on the spin chuck 20A (e.g., onto an upper surface of the substrate). The process fluid may include at least one of a process solution or a process gas. The process fluid may include an etching fluid and/or a cleaning fluid. For example, the process fluid may include an etchant for etching the substrate.

The process fluid supplier 30 may further include a supply shaft 33 provided at one side of the spin chuck 20A and a supply pipe 32 that couples the supply shaft 33 to the nozzle 31. The supply shaft 33 may vertically extend. The supply shaft 33 may move in the vertical direction. Accordingly, a height of the supply shaft 33 may be adjusted, and a level of the nozzle 31 may be adjusted. The supply shaft 33 may also move in a horizontal direction. Accordingly, a location of the nozzle 31 in the horizontal direction may be adjusted. Restated, the nozzle 31 may be movable in the horizontal direction.

The supply pipe 32 may be connected to the nozzle 31 disposed over the spin chuck 20A. The nozzle 31 may be coupled in fluid communication (e.g., through supply pipe 32 and/or supply shaft 33) to a fluid source that may include a pump 38 configured to operate to supply (e.g., pump) a process fluid to the nozzle 31 (e.g., through the supply pipe 32 and/or the supply shaft 33). The process fluid may flow through the supply pipe 32 to the nozzle 31.

The nozzle 31 may discharge the process fluid over the spin chuck 20A. Specifically, the nozzle 31 may supply the process fluid onto the substrate loaded on the spin chuck 20A. The nozzle 31 may move in a vertical direction. A level of the nozzle 31 in the vertical direction may be adjusted by the supply shaft 33.

The nozzle 31 may move in the horizontal direction. A level of the nozzle 31 in horizontal direction may be adjusted by the supply shaft 33 and/or the supply pipe 32. Accordingly, a location in the vertical direction and a location in the horizontal direction at which the process fluid is supplied onto the substrate loaded on the spin chuck 20A may be changed. However, to this end, the spin chuck 20A may also move in the horizontal direction.

The spin chuck 20A may support the substrate (e.g., structurally support the substrate, support some or all of the load of the substrate, support some or all of the weight of the substrate, etc.). That is, the substrate may be loaded on the spin chuck 20A. Specifically, the substrate may be disposed on an upper surface 20As of the spin chuck 20A. The spin chuck 20A may fix the loaded substrate (e.g., hold the loaded substrate in place). The spin chuck 20A may rotate the loaded substrate. Specifically, the spin chuck 20A may rotate the substrate in a circumferential direction in a plan view. For example, the spin chuck 20A may rotate the substrate around a central axis 20Ax (“center”, “axis of rotation,” “rotation axis,” etc.) of the spin chuck 20A. The spin chuck 20A may support the substrate such that a center of the substrate is close to and/or intersected by the central axis 20Ax. Accordingly, the process fluid supplier 30 may supply the process fluid to a central portion of the substrate (e.g., to a portion of the substrate at, including, and/or proximate to the central axis 20Ax, and the supplied process fluid may evenly spread in a radial direction on the substrate (e.g., in one or more radial directions extending radially from the central axis 20Ax) by a centrifugal force. The spin chuck 20A may be provided in a container 40.

The container 40 may surround the spin chuck 20A. The container 40 may include a plurality of containers 40. The plurality of containers 40 may be disposed in layers. That is, the plurality of containers 40 may be provided in multiple layers. As shown, the containers 40 may be provided to be coaxial and/or concentric around central axis 20Ax. For example, the container 40 may include first to fourth containers 41, 42, 43, and 44, and a first container 41 may be disposed at the outermost side, a second container 42 may be disposed at an inner side of the first container 41, a third container 43 may be disposed at an inner side of the second container 42, and a fourth container 44 may be disposed at the innermost side.

Outflow passages may be defined between the plurality of containers 40 (e.g., between adjacent containers of the plurality of containers 40). For example, a first outflow passage 410 may be defined between the first container 41 and the second container 42. In addition, a second outflow passage 420 may be defined between the second container 42 and the third container 43. In addition, a third outflow passage 430 may be defined between the third container 43 and the fourth container 44.

The plurality of containers 40 may have different heights. For example, a height of the first container 41 may be larger than a height of the second container 42, the height of the second container 42 may be larger than a height of the third container 43, and the height of the third container 43 may be larger than a height of the fourth container 44. Accordingly, inflow holes of a plurality of outflow passages 410, 420, and 430 may be located at different levels. For example, the inflow hole of the first outflow passage 410 may be located at a higher level than the inflow hole of the second outflow passage 420, and the inflow hole of the second outflow passage 420 may be located at a higher level than the inflow hole of the third outflow passage 430.

The spin chuck 20A may be provided to be movable in a vertical direction. Accordingly, the spin chuck 20A may adjust a level at which the loaded substrate is processed. In other words, the spin chuck 20A may perform different processes at different levels. Accordingly, different process fluids used in different processes may be introduced into different inflow holes provided at different levels. Therefore, the substrate processing apparatus 1A may separately recover different process fluids.

A support shaft 28 may support the spin chuck 20A. In some example embodiments, the support shaft 28 may rotate along with the spin chuck 20A. In some example embodiments, the spin chuck 20A may rotate independently of the support shaft 28. The support shaft 28 may be coupled to a lower portion of the spin chuck 20A. The support shaft 28 may move in a vertical direction (e.g., based on operation of an actuator mechanically coupled to the support shaft 28 and configured to operate based on control by controller 80). A height of the support shaft 28 may be adjusted. Accordingly, a level of the spin chuck 20A may be changed in the vertical direction. The support shaft 28 and/or the spin chuck 20A may be mechanically coupled to a driver 90. The driver 90 may be configured to cause the spin chuck 20A (alone or in combination with the support shaft 28) to rotate around a central axis 20Ax of the spin chuck 20A. The driver 90 may be mechanically coupled to the spin chuck 20A independently of the support shaft 28 and may be configured to cause the spin chuck 20A to rotate independently of the support shaft 28. The driver 90 may include an electric motor, servoactuator, or the like.

Describing the spin chuck 20A in more detail, the spin chuck 20A may include an upper surface on which the substrate is set to be loaded. In some example embodiments, the upper surface of the spin chuck 20A may be a circular shape.

The spin chuck 20A may include a flat portion 22 and a recess portion 21 surrounded by the flat portion 22. The flat portion 22 may extend in a circumferential direction of the spin chuck 20A. Specifically, the flat portion 22 may extend from an edge of the spin chuck 20A in a central direction. For example, the flat portion 22 may be an annular shape.

The flat portion 22 may include an upper surface 22s. As shown, the upper surface 22s may be a flat upper surface. The upper surface 22s of the flat portion 22 may extend in the horizontal direction. The upper surface 22s of the flat portion 22 may be a portion of the upper surface 20As of the spin chuck 20A.

The recess portion 21 may be surrounded by the flat portion 22. Specifically, the recess portion 21 may be surrounded by the flat portion 22 in a plan view. For example, the recess portion 21 may be located at a central portion of the spin chuck 20A, and the flat portion 22 may be located at an outer side (e.g., outer edge) of the recess portion 21.

The recess portion 21 may include an upper surface 21s, interchangeably referred to herein as a recess upper surface, that is lower than the upper surface 22s of the flat portion 22. The upper surface 21s of the recess portion 21 may be the remaining portion of the upper surface 20As of the spin chuck 20A. A level of the upper surface 21s of the recess portion 21 may decrease toward a center of the spin chuck 20A (e.g., central axis 20Ax). In some example embodiments, the upper surface 21s of the recess portion 21 may be a concave curved surface in a downward direction. In some example embodiments, the upper surface 21s of the recess portion 21 may be a sloped straight surface inclined downward toward the center of the spin chuck 20A (e.g., toward central axis 20Ax.

As described herein, a vertical direction (e.g., Z direction) may be a direction extending perpendicular to the upper surface 22s of the flat portion 22 of the spin chuck 20A. As described herein, a horizontal direction (e.g., X direction) may be a direction extending parallel to the upper surface 22s of the flat portion 22 of the spin chuck 20A. For example, as described herein, the flat portion 22 of the spin chuck 20A may surround the recess portion 21 of the spin chuck 20A in a plan view based on the flat portion 22 of the spin chuck 20A surrounding the recess portion 21 of the spin chuck 20A in a horizontal plane extending parallel to the upper surface 22s of the flat portion 22 of the spin chuck 20A.

As described herein, a height, level, or vertical level of an element may be a distance in the vertical direction (e.g., Z direction) of the element from a reference location, for example a bottom surface 1Ab of the substrate processing apparatus 1A. Where a first element is described to be “lower” than a second element, or to have a lower level or height than the second element, it will be understood that the first element is closer to the reference location (e.g., bottom surface 1Ab) than the second element in the vertical direction. Where a first element is described to be “higher” than a second element, or to have a higher level or height than the second element, it will be understood that the first element is further from the reference location (e.g., bottom surface 1Ab) than the second element in the vertical direction.

The spin chuck 20A may include an outlet 250 provided in the upper surface 20As thereof. The outlet 250 may be located at a central portion of the upper surface 20As of the spin chuck 20A. The outlet 250 may be provided in the recess portion 21. Specifically, the outlet 250 may be provided in the upper surface 21s of the recess portion 21. More specifically, the outlet 250 may be located at a central portion of the upper surface 21s of the recess portion 21 (e.g., such that a central axis of the outlet 250 may be coaxial with the central axis 20Ax of the spin chuck 20A).

The outlet 250 may be connected to an outlet passage 2500. The outlet passage 2500 may extend from the inside of the spin chuck 20A to the inside of the support shaft 28. The outlet 250 may be located at one end of the outlet passage 2500. The process fluid may be introduced into the outlet passage 2500 through the outlet 250. Therefore, the process fluid may be discharged.

The spin chuck 20A may include a first inlet 210. The first inlet 210 may be provided in the upper surface 20As of the spin chuck 20A. Specifically, the first inlet 210 may be located in the upper surface 21s of the recess portion 21. The first inlet 210 may include a plurality of first inlets 210 that are spaced apart from each other. The first inlets 210 may be arranged in the circumferential direction in the upper surface 21s of the recess portion 21. For example, six first inlets 210 may be arranged to be spaced a particular (or, alternatively, predetermined) angle from each other in the circumferential direction in the upper surface 21s of the recess portion 21.

The first inlet 210 may be connected to a first inlet passage 2100. The first inlet passage 2100 may be provided in the spin chuck 20A. The first inlet passage 2100 may extend from the inside of the spin chuck 20A to the inside of the support shaft 28. The first inlet 210 may be located at one end of the first inlet passage 2100. In some example embodiments, the first inlet passage 2100 may include a plurality of first inlet passages 2100 connected to the plurality of first inlets 210. In some example embodiments, the first inlet passage 2100 may be a single first inlet passage 2100 connected to the plurality of first inlets 210.

The substrate processing apparatus 1A may include a negative pressure generator 70 set (e.g., configured) to provide (apply) negative pressure through the first inlet 210, for example to apply the negative pressure to an element and/or surface exposed to the first inlet 210. Providing the negative pressure through the first inlet 210 may include causing the pressure (e.g., barometric pressure) of the first inlet 210 (e.g., at the first inlet 210) to be lower than the pressure of a space in which the substrate is disposed (e.g., lower than the ambient barometric pressure external to the substrate processing apparatus 1A). The negative pressure generator 70 may induce suction of a fluid from the space in which the substrate is disposed through the first inlet 210. For example, the negative pressure generator 70 may form the inside of the first inlet 210 as a vacuum or substantially vacuum state (e.g., may induce a vacuum in the interior of the first inlet 210). The negative pressure generator 70 may include a vacuum pump (e.g., at least one vacuum pump) that is configured to suck (e.g., “draw”) the fluid through the first inlet 210 (e.g., draw fluid from the upper surface 20As through the first inlet 210).

The negative pressure generator 70 may be connected to the first inlet passage 2100. For example, the negative pressure generator 70 may be connected to the other end of the first inlet passage 2100 (e.g., opposite from the first inlet 210). Therefore, the first inlet passage 2100 may connect the negative pressure generator 70 to the first inlet 210, and the negative pressure generator 70 may apply a first negative pressure into the first inlet 210 through the first inlet passage 2100 to thereby provide the first negative pressure through the first inlet 210.

The spin chuck 20A may include a second inlet 220. The second inlet 220 may be provided in the upper surface 20As of the spin chuck 20A. Specifically, the second inlet 220 may be located in the upper surface 22s of the flat portion 22. The second inlet 220 may include a plurality of second inlets 220 that are spaced apart from each other. The second inlets 220 may be arranged in the circumferential direction in the upper surface 22s of the flat portion 22. For example, six second inlets 220 may be arranged to be spaced a particular (or, alternatively, predetermined) angle from each other in the circumferential direction in the upper surface 22s of the flat portion 22.

The second inlet 220 may be connected to a second inlet passage 2200. The second inlet passage 2200 may be provided in the spin chuck 20A. The second inlet passage 2200 may extend from the inside of the spin chuck 20A to the inside of the support shaft 28. The second inlet 220 may be located at one end of the second inlet passage 2200. In some example embodiments, the second inlet passage 2200 may include a plurality of second inlet passages 2200 connected to the plurality of second inlets 220. In some example embodiments, the second inlet passage 2200 may be a single second inlet passage 2200 connected to the plurality of second inlets 220.

The negative pressure generator 70 may be further set (e.g., configured) to provide the negative pressure through the second inlet 220. Providing the negative pressure through the second inlet 220 may include forming the pressure of the second inlet 220 lower than the pressure in the space in which the substrate is disposed. The negative pressure generator 70 may suck (e.g., “draw”) a fluid through the second inlet 220. For example, the negative pressure generator 70 may form the inside of the second inlet 220 as a substantially vacuum state (e.g., induce a vacuum in the interior of the second inlet 220). The negative pressure generator 70 may include the vacuum pump that sucks (e.g., “draws”) the fluid through the second inlet 220.

The negative pressure generator 70 may be further connected to the second inlet passage 2200. For example, the negative pressure generator 70 may be connected to the other end of the second inlet passage 2200 (e.g., opposite from the second inlet 220). Therefore, the second inlet passage 2200 may connect the negative pressure generator 70 to the second inlet 220, and the negative pressure generator 70 may apply a second negative pressure into the second inlet 220 through the second inlet passage 2200 to thereby provide the second negative pressure through the second inlet 220.

The substrate processing apparatus 1A may further include lift pins 50 that are movable in the vertical direction. The lift pins 50 may be disposed (e.g., at least partially disposed) in the spin chuck 20A. Specifically, tips 50t of the lift pins 50 may be located in the spin chuck 20A. When the lift pins 50 rise, the lift pins 50 (e.g., the tips 50t thereof) may at least partially protrude from the upper surface 20As of the spin chuck 20A. When the raised lift pins 50 descend, the lift pins 50 (e.g., the tips 50t thereof) may be inserted into the spin chuck 20A. Accordingly, the lift pins 50 may be set to lift the substrate (e.g., based on the substrate being loaded on the spin chuck 20A, for example on the upper surface 20As of the spin chuck 20A).

The spin chuck 20A may include a plurality of lift holes 240 provided in the upper surface 20As thereof. The plurality of lift holes 240 may be provided in each of the recess portion 21 and the flat portion 22. For example, some among the plurality of lift holes 240 may be provided in the recess portion 21 (e.g., the upper surface 21s of the recess portion 21), and the remaining some among the plurality of lift holes 240 may be provided in the flat portion 22 (e.g., the upper surface 22s of the flat portion 22).

The lift pins 50 may vertically move through the lift holes 240 (e.g., the lift pins 50, for example at least the tips 50t thereof, may at least partially extend, protrude, pass, etc. through separate, respective lift holes 240). For example, the lift pins 50 (e.g., at least the tips 50t thereof) may protrude (e.g., may at least partially protrude) from the upper surface 20As of the spin chuck 20A through the lift holes 240 (e.g., through separate, respective lift holes 240). Conversely, the lift pins 50 may be inserted (e.g., may at least partially inserted) into the spin chuck 20A through the lift holes 240 (e.g., through separate, respective lift holes 240). The lift pins 50 may be mechanically coupled to an actuator 92 (e.g., a servoactuator, although example embodiments are not limited thereto) which may be configured to operate to cause the lift pins 50 to move vertically in relation to the spin chuck 20A. In some example embodiments, actuator 92 is absent and the negative pressure generator 70 may be configured to cause the lift pins 50 to move vertically in relation to the spin chuck 20A based on selectively applying a negative pressure (e.g., a vacuum) to a structure mechanically coupled to some or all of the lift pins 50.

The spin chuck 20A may include a plurality of drain grooves 260 recessed from the upper surface 20As thereof. The drain grooves 260 may be connected to the outlet 250. Specifically, the drain grooves 260 may extend between the edge 20Ae of the spin chuck 20A and the outlet 250. The drain grooves 260 may extend from the outlet 250 in the radial direction (which may be a horizontal direction extending radially from the central axis 20Ax). The drain grooves 260 may be spaced a particular (or, alternatively, predetermined) angle from each other in the circumferential direction with respect to the outlet 250. Therefore, the process fluid may flow to the outlet 250 through the drain grooves 260.

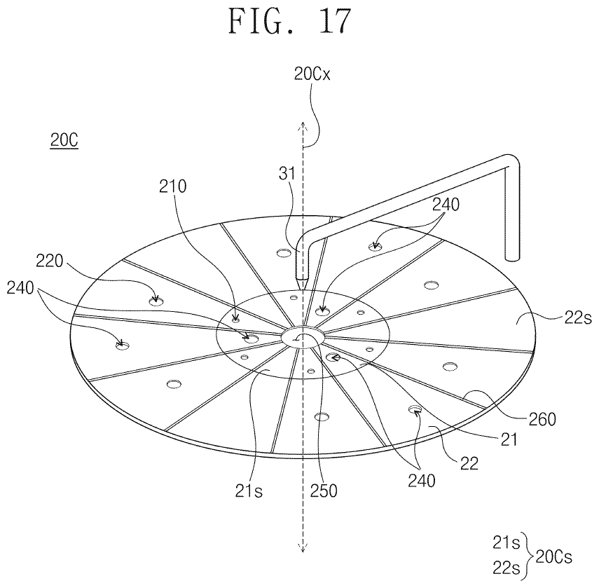

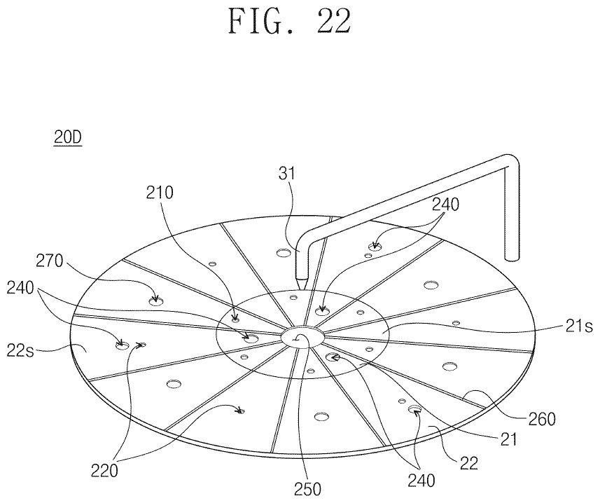

The drain grooves 260 may not overlap the first inlet 210 or the second inlet 220 in a plan view (e.g., a view perpendicular to the vertical direction). The drain grooves 260 may not overlap the lift holes 240 in a plan view. Referring to FIGS. 17 and 22, the drain grooves 260 may not overlap support holes 270 in a plan view.

The substrate processing apparatus 1A may further include a plurality of holding pins 280 disposed at the edge 20Ae of the spin chuck 20A. The holding pins 280 may be spaced apart from each other in the circumferential direction along the edge of the spin chuck 20A. The holding pins 280 may come into contact with an edge of the substrate loaded on the spin chuck 20A. Therefore, the holding pins 280 may fix the substrate loaded on the spin chuck 20A in the horizontal direction (e.g., X direction). In addition, the holding pins 280 may prevent the substrate rotating by the spin chuck 20A from being detached by the centrifugal force, or reduce or minimize the likelihood of such detachment.

In some example embodiments, the substrate processing apparatus 1A may include a controller 80 that is communicatively coupled to the negative pressure generator 70, the pump 38, the driver 90, the actuator 92, or any combination thereof. The controller 80 may be configured to control operation of one or more of the negative pressure generator 70 (e.g., the first negative pressure generator 71 and/or the second negative pressure generator 72) to control the configured operation of the negative pressure generator 70 (e.g., the first negative pressure generator 71 and/or the second negative pressure generator 72) as described herein. The controller 80 may be configured to control the supplying of one or more process fluids by the process fluid supplier 30 as described herein, for example based on controlling operation of one or more pumps 38. The controller 80 may be configured to control the rotating of the spin chuck 20A, for example based on controlling operation of a driver 90. The controller 80 may be configured to control the vertical movement of the lift pins 50, for example based on controlling operation of an actuator 92 and/or the negative pressure generator 70. The controller 80 may include a memory (e.g., a solid-state drive) storing a program of instructions and a processor (e.g., a central processing unit or CPU) configured to execute the program of instructions to control operation of the substrate processing apparatus 1A and/or any portion thereof (e.g., the negative pressure generator 70, the pump 38, the driver 90, the actuator 92, etc.).

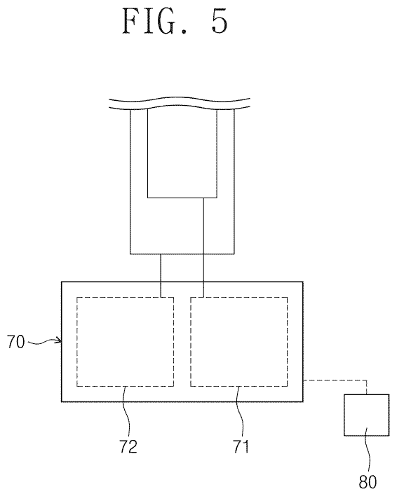

FIG. 5 is a conceptual diagram of the negative pressure generator 70 according to some example embodiments of the present inventive concepts.

Referring to FIGS. 1 and 5, the negative pressure generator 70 may be independently connected to the first inlet passage 2100 and the second inlet passage 2200. Therefore, the negative pressure generator 70 may independently control the first inlet passage 2100 and the second inlet passage 2200. That is, the negative pressure generator 70 may apply the negative pressure only to the first inlet passage 2100 or only to the second inlet passage 2200. Alternatively, the negative pressure generator 70 may simultaneously apply the negative pressure to the first inlet passage 2100 and the second inlet passage 2200.

Referring to FIG. 5, in some example embodiments, the negative pressure generator 70 may include a first negative pressure generator 71 (e.g., a first vacuum pump) connected to the first inlet passage 2100 and a second negative pressure generator 72 (e.g., a second vacuum pump) connected to the second inlet passage 2200. The first negative pressure generator 71 and the second negative pressure generator 72 may independently operate (e.g., such that the negative pressure generator 70 is configured to independently apply the first negative pressure and the second negative pressure). For example, the first negative pressure generator 71 and the second negative pressure generator 72 may be set (e.g., configured) to operate asynchronously. That is, the first negative pressure generator 71 and the second negative pressure generator 72 may not simultaneously apply the negative pressure to the first inlet passage 2100 and the second inlet passage 2200, and only one of the first negative pressure generator 71 or the second negative pressure generator 72 may operate. The controller 80 may control the negative pressure generator 70 to independently operate the first and second negative pressure generators 71 to independently provide (apply) the first and negative pressures to the first and second inlet passages 2100 and 2200, respectively.

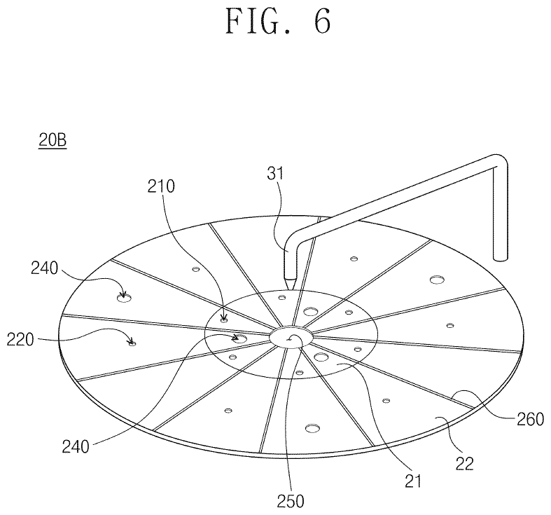

FIG. 6 is a perspective view of a spin chuck 20B according to some example embodiments of the present inventive concepts.

Referring back to FIG. 2, in some example embodiments, each of the second inlets 220 may be located on the same lines as each of the first inlets 210. That is, the second inlets 220 may be spaced apart from the first inlets 210 in the radial direction. For example, the first inlets 210 and the second inlets 220 may be located on three horizontal lines passing through the center of the upper surface of the spin chuck 20A.

Alternatively, referring to FIG. 6, in some example embodiments, each of the second inlets 220 may not be located on the horizontal line passing through the center of the upper surface of the spin chuck 20B in which the first inlets 210 are located. That is, the first inlets 210 and the second inlets 220 may be spaced a particular (or, alternatively, predetermined) angle from each other in the circumferential direction. The first inlets 210 and the second inlets 220 may be alternately arranged at a particular (or, alternatively, predetermined) angle in the circumferential direction.

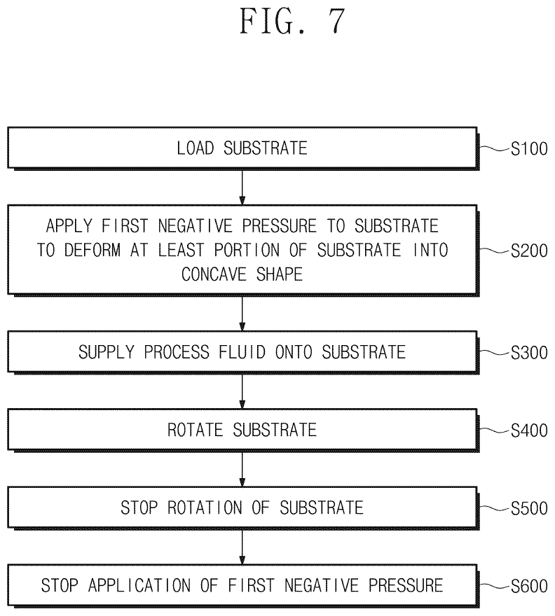

FIG. 7 is a flowchart showing an operation method of a substrate processing apparatus of the present inventive concepts. The operation method shown in FIG. 7 may be implemented based on operation of the substrate processing apparatus 1A, which may further be implemented based on operation of a controller 80 to control one or more portions of the substrate processing apparatus 1A. For example, the operation method shown in FIG. 7 may be implemented based a processor of the controller 80 executing a program of instructions stored in a memory of the controller 80 to control one or more portions of the substrate processing apparatus 1A.

Referring to FIG. 7, an operation method of the substrate processing apparatus (hereinafter, referred to as “operation method”) may include loading a substrate (e.g., loading the substrate on the spin chuck 20A) (S100), applying the first negative pressure to the substrate to deform at least a portion of the substrate into a concave shape (S200), supplying the process fluid onto the substrate (S300), rotating the substrate (S400), stopping the rotation of the substrate (S500), and stopping the application of the first negative pressure (S600). In some example embodiments, the operation method may further include applying the second negative pressure to the substrate to fix the substrate. The operation method may be implemented based on operation of the controller 80 to control the operation of one or more portions of the substrate processing apparatus 2A.

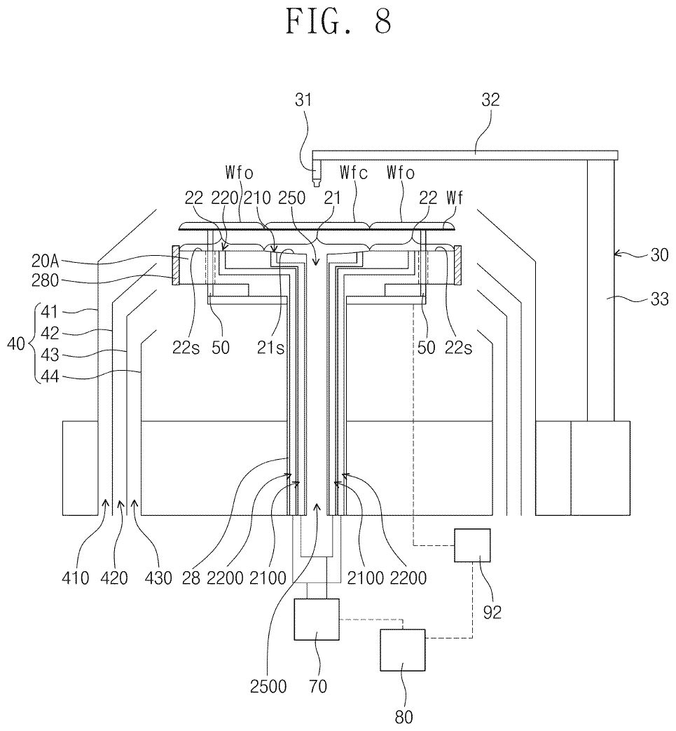

Hereinafter, the operation method will be described in more detail with reference to FIGS. 8 to 16.

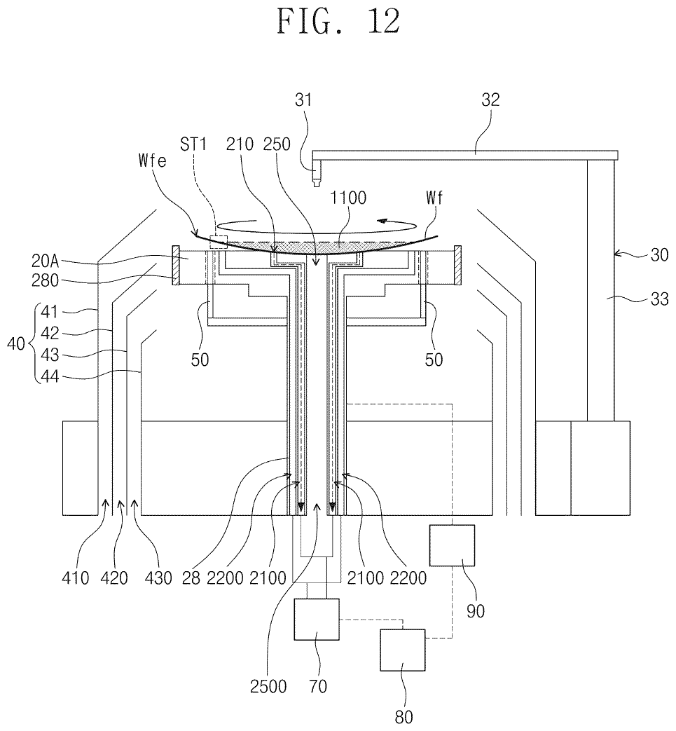

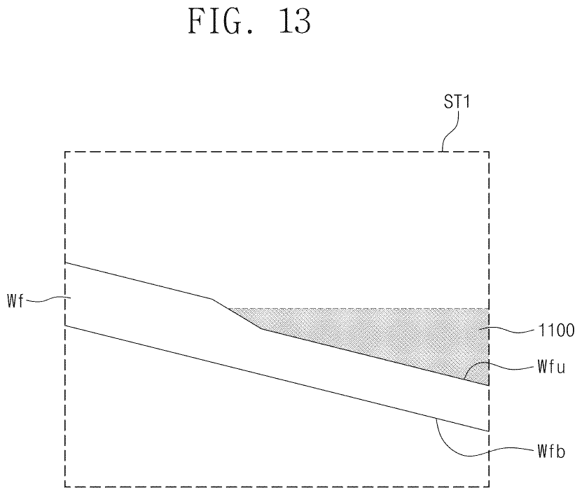

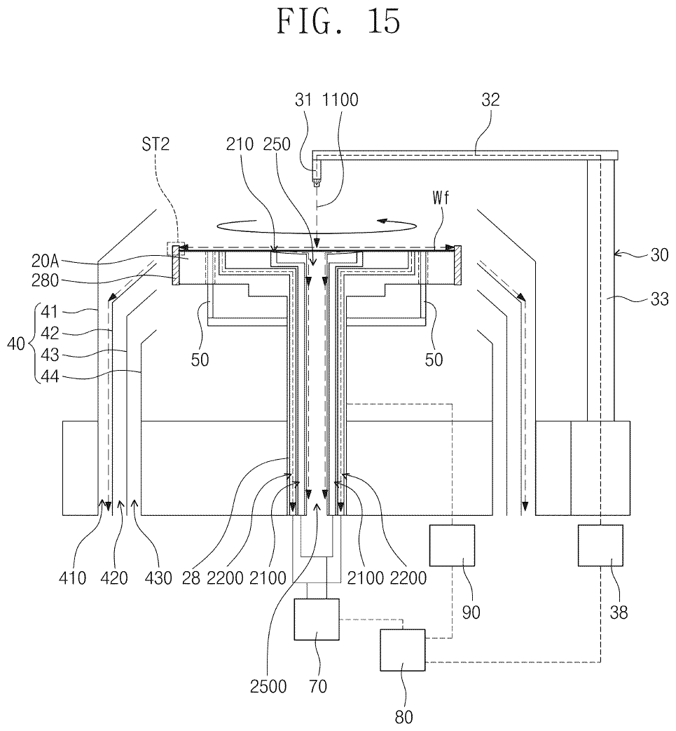

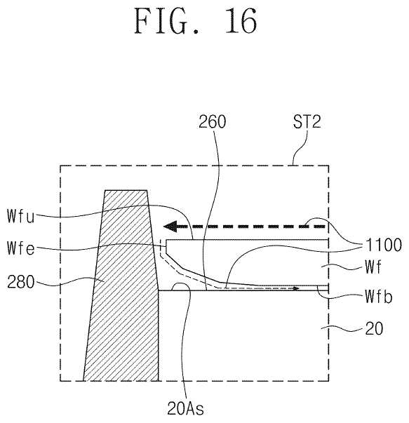

FIGS. 8, 9, 10, 11, 12, 14, and 15 are views showing the operation method of the substrate processing apparatus of the present inventive concepts. FIG. 13 is an enlarged view of region ST1 of FIG. 12. FIG. 16 is an enlarged view of region ST2 of FIG. 15. The operation methods shown in FIGS. 8 to 16 may be implemented based on operation of the substrate processing apparatus 1A, which may further be implemented based on operation of a controller 80 to control one or more portions of the substrate processing apparatus 1A. For example, the operation methods shown in FIGS. 8 to 16 may be implemented based a processor of the controller 80 executing a program of instructions stored in a memory of the controller 80 to control one or more portions of the substrate processing apparatus 1A.

Referring to FIGS. 7 to 9, the loading of the substrate (S100) may include locating (e.g., loading) the substrate Wf on the spin chuck 20A. The lift pins 50 (e.g., at least the tips 50t thereof) may rise to protrude (e.g., at least partially protrude) from the upper surface 20As of the spin chuck 20A. The protruded lift pins 50 may lift the substrate Wf transported on the spin chuck 20A by an arm (e.g., based on operation of an actuator 92 mechanically coupled to the arm). The raised lift pins 50 may descend again (e.g., based on operation of an actuator 92 mechanically coupled to the arm). Accordingly, the lifted substrate Wf may gradually descend by the lift pins 50. The lift pins 50 (e.g., at least the tips 50t thereof) may be inserted into the spin chuck 20A (e.g., through upper surface 20As), and the substrate Wf may be loaded onto the spin chuck 20A (e.g., into contact with the upper surface 22s of the flat portion 22). As shown, the substrate Wf may initially be planar such that an outer portion Wfo of the loaded substrate Wf at S100 that overlaps (e.g., overlaps in the vertical direction Z) the flat portion 22 may be in contact with the upper surface 22s of the flat portion 22 of the spin chuck 20A and a central portion Wfc of the substrate Wf that overlaps (e.g., overlaps in the vertical direction Z) the recess portion 21 may be spaced apart from the upper surface 21s of the recess portion 21 of the spin chuck 20A in the vertical direction. In some example embodiments, the substrate processing apparatus 2A may be configured to raise and/or lower the lift pins 50 based on operation of the negative pressure generator 70 and/or an actuator 92.

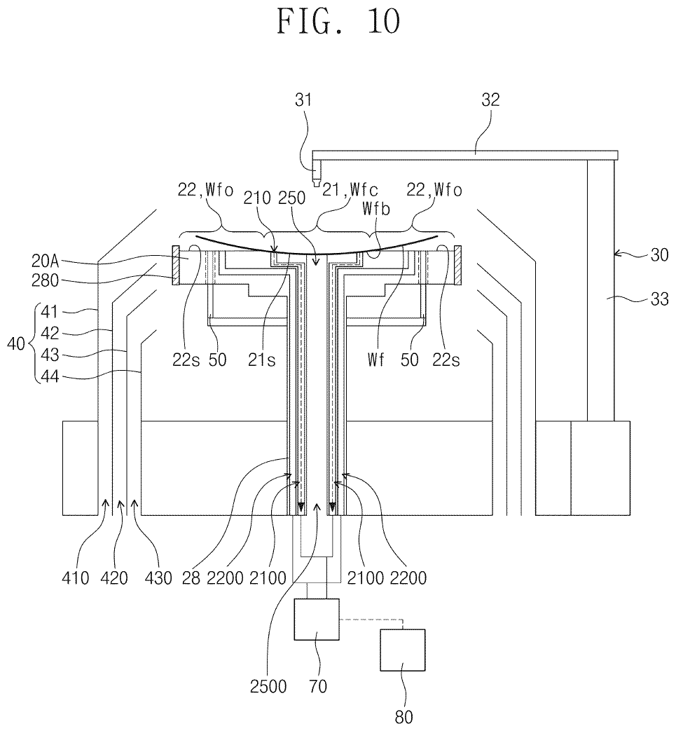

Referring to FIGS. 7 and 10, the applying of the first negative pressure to the substrate Wf to deform at least a portion of the substrate Wf (e.g., at least the central portion Wfc) into the concave shape (S200) may be performed after the loading of the substrate (S100). As shown, the substrate Wf may be initially in a rest shape (e.g., during the loading at S100), which may be a flat shape, planar shape, etc. The deforming into the concave shape as described herein may include deforming the substrate Wf from the rest shape (e.g., planar shape) into the concave shape. The applying of the first negative pressure to the substrate Wf to deform at least a portion of the substrate Wf (e.g., at least the central portion Wfc) into the concave shape (S200) may include operating the negative pressure generator 70. Specifically, the applying of the first negative pressure to the substrate Wf to deform at least a portion of the substrate (e.g., at least the central portion Wfc) into the concave shape (S200) may include applying the first negative pressure to the loaded substrate Wf (e.g., at least the central portion Wfc) through the negative pressure generator 70.

The first negative pressure may be applied to a bottom surface Wfb of the substrate Wf (e.g., a bottom surface Wfb of the central portion Wfc) through the first inlet 210 (the bottom surface of the substrate Wf facing toward the upper surface 20As of the spin chuck 20A). The substrate Wf (e.g., at least the central portion Wfc) may come into close contact with the first inlet 210 by the applied first negative pressure. The negative pressure generator 70 may apply the first negative pressure to the bottom surface Wfb of the substrate Wf through the first inlet 210, and the substrate Wf (e.g., at least the central portion Wfc) may come into close contact (also referred to interchangeably herein as contact or direct contact) with the recess portion 21 in which the first inlet 210 are located (e.g., into contact with the upper surface 21s of the recess portion 21). For example, the central portion Wfc of the substrate Wf may be drawn into contact with the upper surface 21s of the recess portion 21 based on exposing a bottom surface Wfb of the central portion Wfc of the substrate Wf to the first negative pressure provided through the first inlet 210 to thereby cause the central portion Wfc of the substrate Wf into contact with the upper surface 21s of the recess portion 21 in which the first inlet 210 is located. Accordingly, the substrate Wf may be concavely deformed (e.g., deformed from a rest shape such as a planar shape to a concave shape) according to a shape of the recess portion 21 and may be fixed to the first inlet 210. For example, the substrate Wf may be concavely deformed according to a shape of the upper surface 21s of the recess portion 21 based on a central portion Wfc of the substrate Wf being drawn into contact with the upper surface 21s and thereby deforming at least the central portion Wfc of the substrate Wf to a shape conforming to the shape defined by the upper surface 21s of the recess portion 21. As shown, the deforming may cause an outer portion Wfo of the substrate Wf that is in contact with the upper surface 22s of the flat portion 22 at S100 to become spaced apart from the upper surface 22s based on the substrate Wf being concavely deformed at S200.

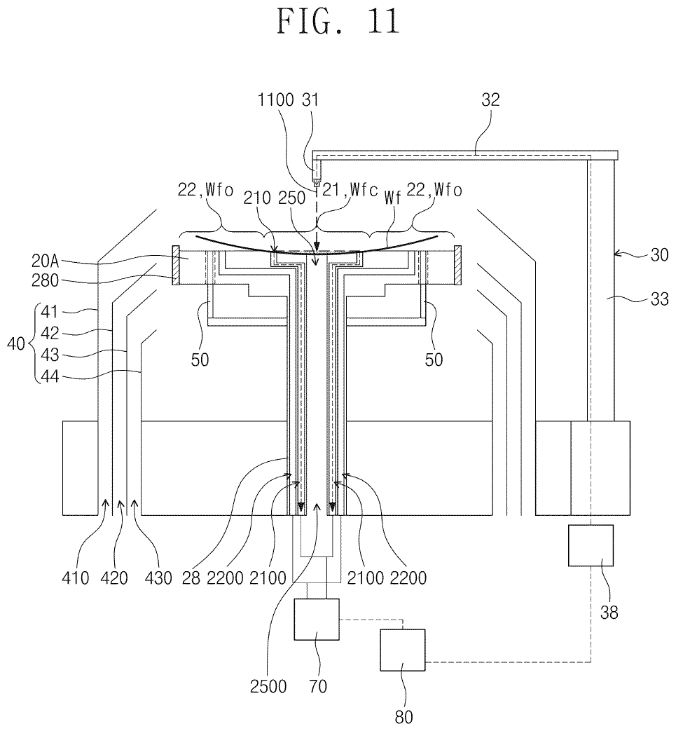

Referring to FIGS. 7 and 11, the supplying of the process fluid 1100 onto the substrate (S300) may be performed (e.g., based on control of a pump 38 by the controller 80) after (e.g., subsequent to) the loading of the substrate (S100) and the applying of the first negative pressure to deform at least a portion of the substrate into the concave shape (S200). The process fluid 1100 may include an etchant that etches the substrate Wf. The supplying of the process fluid 1100 onto the substrate (S300) may be performed (e.g., based on control of a pump 38 by the controller 80) concurrently with maintaining the providing of the first negative pressure through the one or more first inlets 210 maintain the deformed concave shape of at least the central portion of the substrate Wf (S200).

The supplying the process fluid 1100 onto the substrate (S300) may include supplying the process fluid 1100 onto the substrate Wf (e.g., onto the upper surface Wfu thereof) through the process fluid supplier 30 (e.g., based on operation of a pump 38). Specifically, the process fluid supplier 30 may supply the process fluid 1100 onto the concavely deformed substrate Wf through the nozzle 31 located over the substrate Wf. The supplied process fluid 1100 may be contained in the concavely deformed substrate Wf. For example, as shown in at least FIGS. 11-13, the supplied process fluid 1100 may be contained in a volume having a lower boundary defined by a concave surface, where the concave surface is defined by at least a portion of the upper surface Wfu of the concavely deformed substrate Wfu. Accordingly, as shown in at least FIGS. 11-13, the process fluid 1100 may be understood to be contained on a concave surface defined by an upper surface Wfu of the substrate Wf concurrently with the substrate Wf being in the deformed, concave shape.

In some example embodiments, while supplying the process fluid 1100 onto the substrate Wf, a positional relationship of the nozzle 31 and the spin chuck 20A in the horizontal direction may be changed. That is, while supplying the process fluid 1100 onto the substrate Wf, at least one of the nozzle 31 or the spin chuck 20A may move in the horizontal direction. Accordingly, the process fluid 1100 may be evenly supplied onto the substrate Wf.

Referring to FIGS. 7, 12, and 13, in some example embodiments, the rotating of the substrate (S400) may be performed after the supplying of the process fluid 1100 onto the substrate (S300). The rotating may be performed based on operation of a driver 90 (e.g., an electric motor, servoactuator, or the like) that is mechanically coupled to the spin chuck 20A, for example coupled to the spin chuck 20A through the support shaft 28. In some example embodiments, the rotating of the substrate (S400) may be performed in real time during (e.g., at least partially concurrently to) the supplying of the process fluid 1100 onto the substrate (S300). That is, the process fluid 1100 may be supplied onto the rotating substrate Wf. In some example embodiments, in the rotating of the substrate (S400), the spin chuck 20A may rotate the substrate Wf at a particular (or, alternatively, predetermined) speed or less so that the process fluid 1100 contained in the concavely deformed substrate Wf does not overflow.

By the rotating of the substrate (S400), the substrate Wf may be etched. That is, while rotating the substrate Wf, a thickness of the substrate Wf may decrease. Specifically, as shown in at least FIG. 13, at least a portion of the substrate Wf that comes into contact with the process fluid 1100 (e.g., the process fluid 1100 contained on the concavely deformed upper surface Wfu of the concave-deformed substrate Wfu) may be etched. The process fluid 1100 contained in the concavely deformed substrate Wf (e.g., on the concavely deformed upper surface Wfu) may come into contact with at least a portion of an upper surface Wfu of the substrate Wf, and at least a portion of the upper surface Wfu of the substrate Wf may be etched by the process fluid 1100. When the spin chuck 20A rotates the substrate Wf at a particular (or, alternatively, predetermined) speed or less so that the process fluid 1100 contained in the concavely deformed substrate Wf does not overflow by the centrifugal force, the upper surface Wfu of the substrate Wf may come into contact with the process fluid 1100, but the edge Wfe of the substrate Wf may not come into contact with the process fluid 1100. Accordingly, the edge Wfe of the substrate Wf may not be etched by the process fluid 1100. That is, the spin chuck 20A may allow the process fluid 1100 to selectively etch the upper surface Wfu of the substrate Wf (e.g., the upper surface of a central portion of the substrate Wf that omits an outer portion of the substrate Wfu surrounding the central portion and further omitting the edge Wfe of the substrate Wf).

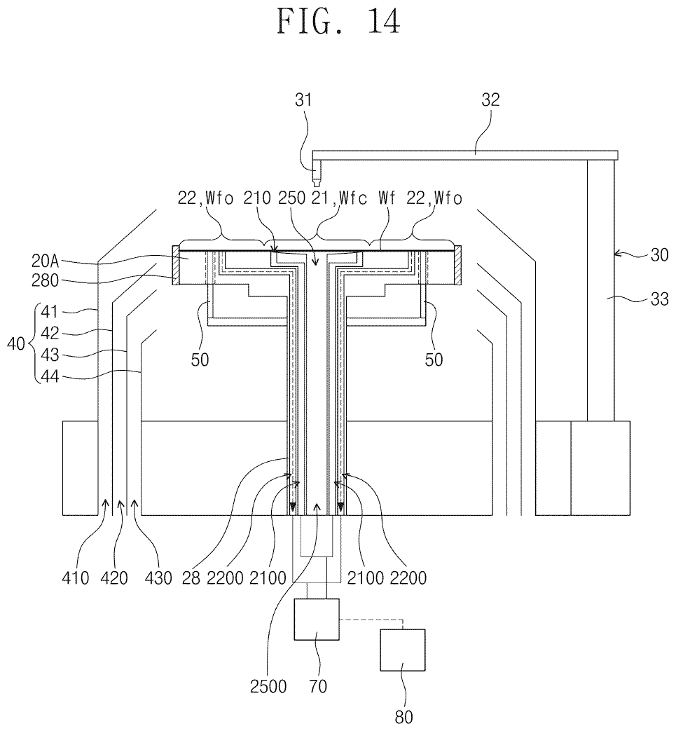

Referring to FIG. 14, after the stopping of the rotation of the substrate (S500), the stopping of the application of the first negative pressure (S600) may be performed. That is, after the rotation of the substrate Wf is stopped, the application of the first negative pressure may be stopped. Accordingly, since the application of the first negative pressure is maintained until the rotation of the substrate Wf is stopped, the phenomenon of the substrate Wf being detaching from the spin chuck by the centrifugal force can be reduced or minimized.

Alternatively, in some example embodiments, the stopping of the rotation of the substrate (S500) may be performed in real time during (e.g., concurrently with) the stopping of the application of the first negative pressure (S600). In some example embodiments, the stopping the application of the first negative pressure (S600) may be performed before (e.g., prior to) the stopping of the rotation of the substrate (S500).

When the application of the first negative pressure is stopped (e.g., based on the application of the first negative pressure being stopped), the concavely deformed substrate Wf may be deformed back to its original state (e.g., a rest shape, which may be a flat shape, a planar shape, or the like). That is, when the application of the first negative pressure is stopped (e.g., based on the application of the first negative pressure being stopped), the concavely deformed substrate Wf may be deformed back to a rest shape, for example a flat shape, a planar shape, or the like.

The applying of the second negative pressure to the substrate Wf to fix the substrate Wf (e.g., based on operation of the negative pressure generator 70) may be performed after (e.g., subsequent to) the stopping of the rotation of the substrate (S500). The applying of the second negative pressure to the substrate Wf to fix the substrate Wf may be performed after (e.g., subsequent to) the stopping of the application of the first negative pressure (S600). That is, after the concavely deformed substrate Wf is restored to the flat shape, the second negative pressure may be applied to the substrate Wf.

In some example embodiments, the applying of the second negative pressure to the substrate Wf to fix the substrate Wf may be performed before (e.g., prior to) the stopping of the application of the first negative pressure (S600). That is, the first negative pressure and the second negative pressure may be simultaneously applied to the substrate Wf. In this case, the central portion of the substrate Wf may be deformed into a concave shape, and the edge portion of the substrate Wf may be deformed into a flat shape.

The applying of the second negative pressure to the substrate Wf to fix the substrate Wf may include operating the negative pressure generator 70 (e.g., based on operation of the controller 80). When the negative pressure generator 70 is operated to apply the second negative pressure to the substrate Wf (e.g., to a bottom surface Wfb of the substrate Wf at the outer portion Wfo of the substrate Wf that vertically overlaps the flat portion 22 of the spin chuck 20A), the concavely deformed substrate Wf may be deformed back into the flat shape (rest shape) by the second negative pressure.

The second negative pressure may be applied to the bottom surface Wfb of the substrate Wf (e.g., the outer portion Wfo thereof) through the second inlet 220. The substrate Wf may come into close contact with the second inlet 220 by the applied second negative pressure. The negative pressure generator 70 may apply the second negative pressure to the bottom surface Wfb of the substrate Wf (e.g., the outer portion Wfo thereof) through the second inlet 220, and the substrate Wf may come into close contact with the flat portion 22 in which the second inlet 220 is located. Accordingly, the substrate Wf may be flatly deformed according to a shape of the flat portion 22 and may be fixed to the second inlet 220.

Referring to FIGS. 15 and 16, the supplying of the process fluid 1100 onto the substrate (S300) and the rotating of the substrate (S400) may be performed after the applying of the second negative pressure to the substrate to fix the substrate. In some example embodiments, the supplying of the process fluid 1100 onto the substrate (S300) may be performed after the rotating of the substrate (S400). In some example embodiments, the supplying of the process fluid 1100 onto the substrate (S300) may be performed in real time during the rotating of the substrate (S400). Accordingly, the process fluid 1100 may be supplied onto the rotating substrate Wf.

While the process fluid 1100 is supplied onto the rotating substrate Wf, the substrate Wf may be etched. The process fluid 1100 supplied to the central portion Wfc of the substrate Wf may flow toward the edge Wfe of the substrate Wf by the centrifugal force. Accordingly, the process fluid 1100 may etch the upper surface Wfu and the edge Wfe of the substrate Wf together. At least a portion of the process fluid 1100 may flow between the bottom surface Wfb of the substrate Wf and the spin chuck 20A along the edge of the substrate Wf. Accordingly, the process fluid 1100 may also etch the bottom surface of the substrate Wf.

The process fluid 1100 flowing between the bottom surface Wfb of the substrate Wf and the spin chuck 20A may be discharged through the outlet 250 located at the central portion of the spin chuck 20A. The drain grooves 260 provided in the upper surface 20As of the spin chuck 20A may guide the process fluid 1100 flowing between the bottom surface Wfb of the substrate Wf and the spin chuck 20A (e.g., the upper surface 20As thereof) to the outlet 250. The process fluid 1100 introduced into the outlet 250 may be discharged from the spin chuck 20A through the outlet passage 2500 provided in the support shaft 28.

The process fluid 1100 flowing along the upper surface Wfu of the substrate Wf may be introduced into an outflow passage formed between the containers 40 by the centrifugal force. For example, the process fluid may be introduced into an inflow hole of the first outflow passage 410 formed between the first container 41 and the second container 42 by the centrifugal force. Accordingly, the process fluid 1100 introduced into the first outflow passage 410 may be recovered.

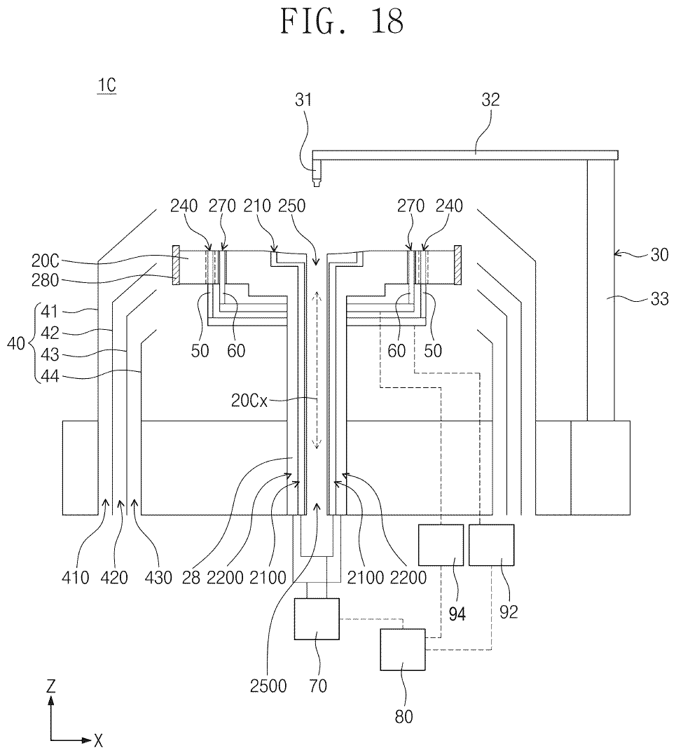

FIG. 17 is a perspective view of a spin chuck 20C according to some example embodiments of the present inventive concepts. FIG. 18 is a view showing a substrate processing apparatus 1C according to some example embodiments of the present inventive concepts.

Referring to FIGS. 17 and 18, the substrate processing apparatus 1C may include a process fluid supplier 30 that is the same or substantially the same as the process fluid supplier 30 of FIGS. 1 to 4 and a container 40 that is substantially the same as the container 40 of FIGS. 1 to 4.

The substrate processing apparatus 1C may include a spin chuck 20C that supports a substrate. That is, the substrate may be loaded on the spin chuck 20C. Specifically, the substrate may be disposed on an upper surface of the spin chuck 20C. The spin chuck 20C may fix the loaded substrate. The spin chuck 20C may rotate the loaded substrate. Specifically, the spin chuck 20A may rotate the substrate in a circumferential direction in a plan view. Accordingly, the process fluid supplier 30 may supply the process fluid to a central portion of the substrate, and the supplied process fluid may evenly spread in a radial direction on the substrate by a centrifugal force. The spin chuck 20C may be provided in a container 40.

The spin chuck 20C may be provided to be movable in a vertical direction (e.g., based on operation of an actuator mechanically coupled to the spin chuck 20C and based on control of the actuator by a controller 80). Accordingly, the spin chuck 20C may adjust a level at which the loaded substrate is processed. In other words, the spin chuck 20C may perform different processes at different levels. Accordingly, different process fluids used in different processes may be introduced into different inflow holes provided at different levels. Therefore, the substrate processing apparatus 1C may separately recover different process fluids.

The support shaft 28 may support the spin chuck 20C. In some example embodiments, the support shaft 28 may rotate along with the spin chuck 20C (e.g., based on operation of a driver 90 as shown in at least FIG. 1). In some example embodiments, the spin chuck 20C may rotate independently of the support shaft 28 (e.g., the spin chuck 20C may be mechanically coupled to the driver 90 independently of the support shaft 28). The support shaft 28 may be coupled to a lower portion of the spin chuck 20C. The support shaft 28 may move in the vertical direction (e.g., based on operation of an actuator mechanically coupled to the support shaft 28). A height of the support shaft 28 may be adjusted. Accordingly, a level of the spin chuck 20C may be changed in the vertical direction.

Describing the spin chuck 20C in more detail, the spin chuck 20C may include an upper surface on which the substrate is set to be loaded. In some example embodiments, the upper surface of the spin chuck 20C may be a circular shape.

The spin chuck 20C may include the flat portion 22 and the recess portion 21 surrounded by the flat portion 22. The flat portion 22 may extend in a circumferential direction of the spin chuck 20C. Specifically, the flat portion 22 may extend from an edge of the spin chuck 20C in a central direction. For example, the flat portion 22 may be an annular shape.

The flat portion 22 may include an upper surface 22s which may be referred to herein interchangeably as a flat upper surface. The upper surface 22s of the flat portion 22 may extend in a horizontal direction (e.g., direction X). The upper surface 22s of the flat portion 22 may be a portion of the upper surface 20Cs of the spin chuck 20C.

The recess portion 21 may be surrounded by the flat portion 22. Specifically, the recess portion 21 may be surrounded by the flat portion 22 in a plan view. For example, the recess portion 21 may be located at a central portion of the spin chuck 20C, and the flat portion 22 may be located at an outer side (e.g., outer edge) of the recess portion 21.

The recess portion 21 may include an upper surface 21s lower than the upper surface 22s of the flat portion 22. The upper surface 21s of the recess portion 21 may be the remaining portion of the upper surface 20Cs of the spin chuck 20C. A level of the upper surface 21s of the recess portion 21 may decrease toward a center (e.g., central axis 20Cx) of the spin chuck 20C. In some example embodiments, the upper surface 21s of the recess portion 21 may be concave in a downward direction. In some example embodiments, the upper surface 21s of the recess portion 21 may be a sloped surface inclined downward toward the center (e.g., central axis 20Cx) of the spin chuck 20C.

The spin chuck 20C may include the outlet 250 provided in the upper surface 20Cs thereof. The outlet 250 may be located at a central portion of the upper surface 20Cs of the spin chuck 20C. The outlet 250 may be provided in the recess portion 21. Specifically, the outlet 250 may be provided in the upper surface 21s of the recess portion 21. More specifically, the outlet 250 may be located at a central portion of the upper surface 21s of the recess portion 21.

The outlet 250 may be connected to the outlet passage 2500. The outlet passage 2500 may be provided inside the support shaft 28. The outlet 250 may be located at one end of the outlet passage 2500. The process fluid may be introduced into the outlet passage 2500 through the outlet 250. Therefore, the process fluid may be discharged.

The spin chuck 20C may include the first inlet 210. The first inlet 210 may be provided in the upper surface 20Cs of the spin chuck 20C. Specifically, the first inlet 210 may be located in the upper surface 21s of the recess portion 21. The first inlet 210 may include a plurality of first inlets 210 that are spaced apart from each other. The first inlets 210 may be arranged in the circumferential direction in the upper surface 21s of the recess portion 21. For example, six first inlets 210 may be arranged to be spaced a particular (or, alternatively, predetermined) angle from each other in the circumferential direction in the upper surface 21s of the recess portion 21.

The first inlet 210 may be connected to the first inlet passage 2100. The first inlet passage 2100 may be provided in the spin chuck 20C. The first inlet passage 2100 in the spin chuck 20C may extend into the support shaft 28. The first inlet 210 may be located at one end of the first inlet passage 2100. In some example embodiments, the first inlet passage 2100 may include a plurality of first inlet passages 2100 connected to the plurality of first inlets 210. In some example embodiments, the first inlet passage 2100 may be a single first inlet passage 2100 connected to the plurality of first inlets 210.

The substrate processing apparatus 1C may include a negative pressure generator 70 set (e.g., configured) to provide (apply) negative pressure through the first inlet 210 for example to apply the negative pressure to an element and/or surface exposed to the first inlet 210. Providing the negative pressure through the first inlet 210 may include causing the pressure (e.g., barometric pressure) of the first inlet 210 (e.g., at the first inlet 210) to be lower than the pressure of a space in which the substrate is disposed (e.g., lower than the ambient barometric pressure external to the substrate processing apparatus 1C). The negative pressure generator 70 may suck (e.g., “draw”) a fluid through the first inlet 210. For example, the negative pressure generator 70 may form the inside of the first inlet 210 as a substantially vacuum state. The negative pressure generator 70 may include a vacuum pump that sucks (e.g., “draws”) the fluid through the first inlet 210.

The negative pressure generator 70 may be connected to the first inlet passage 2100. For example, the negative pressure generator 70 may be connected to the other end of the first inlet passage 2100. Therefore, the first inlet passage 2100 may connect the negative pressure generator 70 to the first inlet 210, and the negative pressure generator 70 may apply a first negative pressure into the first inlet 210 through the first inlet passage 2100.

The substrate processing apparatus 1C may include support pins 60 that are movable in the vertical direction. The support pins 60 may be disposed in (e.g., at least partially in) the spin chuck 20C. Specifically, tips of the support pins 60 may be located in the spin chuck 20C. When the support pins 60 rise, the support pins 60 may protrude from the upper surface 20Cs of the spin chuck 20C. When the raised support pins 60 descend, the support pins 60 may be inserted into the spin chuck 20C. Accordingly, the support pins 60 may be set (e.g., configured) to support the substrate.

The spin chuck 20C may include a plurality of support holes 270 provided in the upper surface 20Cs thereof. The plurality of support holes 270 may be provided in the flat portion 22 (e.g., in the upper surface 22s of the flat portion 22). The support holes 270 may be arranged in the flat portion 22 in the circumferential direction. For example, six support holes 270 may be arranged to be spaced a particular (or, alternatively, predetermined) angle from each other in the circumferential direction in the flat portion 22.

The support pins 60 (e.g., at least the tips 60t thereof) may at least partially vertically move through the support holes 270. For example, the support pins 60 (e.g., the tips 60t thereof) may protrude from the upper surface 20Cs of the spin chuck 20C through the support holes 270 (e.g., the tips 60t may protrude through separate, respective support holes 270). Conversely, the support pins 60 (e.g., the tips 60t thereof) may be inserted into the spin chuck 20C through the support holes 270 (e.g., the tips 60t may be inserted into separate, respective support holes 270). The support pins 60 may be mechanically coupled to an actuator 94 (e.g., a servoactuator, although example embodiments are not limited thereto) which may be configured to operate to cause the support pins 60 to move vertically in relation to the spin chuck 20C. In some example embodiments, actuator 94 is absent and the negative pressure generator 70 may be configured to cause the support pins 60 to move vertically in relation to the spin chuck 20A based on selectively applying a negative pressure (e.g., a vacuum) to a structure mechanically coupled to some or all of the support pins 60. The controller 80 may be communicatively coupled to the actuator 94 and/or the negative pressure generator 70 and may be configured to control the movement of the support pins 60 based on controlling one or more of the actuator 94 and/or the negative pressure generator 70.

The substrate processing apparatus 1C may further include lift pins 50 that are movable in the vertical direction (e.g., based on operation of actuator 92 and/or negative pressure generator 70). The lift pins 50 may be disposed in (e.g., at least partially in) the spin chuck 20C. Specifically, tips 50t of the lift pins 50 may be located in (e.g., at least partially in) the spin chuck 20C. When the lift pins 50 rise, the lift pins 50 (e.g., the tips 50t thereof) may protrude from the upper surface 20Cs of the spin chuck 20C. When the raised lift pins 50 descend, the lift pins 50 (e.g., the tips 50t thereof) may be inserted into the spin chuck 20C. Accordingly, the lift pins 50 may be set to lift the substrate.

The spin chuck 20C may include a plurality of lift holes 240 provided in the upper surface 20Cs thereof. The plurality of lift holes 240 may be provided in each of the recess portion 21 and the flat portion 22. For example, some among the plurality of lift holes 240 may be provided in the recess portion 21 (e.g., the upper surface 21s thereof), and the remaining some among the plurality of lift holes 240 may be provided in the flat portion 22 (e.g., the upper surface 22s thereof).

The lift pins 50 (e.g., at least the tips 50t thereof) may at least partially vertically move through the lift holes 240. For example, the lift pins 50 may protrude from the upper surface of the spin chuck 20C through the lift holes 240 (e.g., the tips 50t may protrude through separate, respective lift holes 240). Conversely, the lift pins 50 (e.g., the tips 50t thereof) may be inserted into the spin chuck 20C through the lift holes 240 (e.g., separate, respective lift holes 240).

The spin chuck 20C may include a plurality of drain grooves 260 recessed from the upper surface thereof. The drain grooves 260 may be connected to the outlet 250. Specifically, the drain grooves 260 may extend between the edge of the spin chuck 20C and the outlet 250. The drain grooves 260 may extend from the outlet 250 in the radial direction. The drain grooves 260 may be spaced a particular (or, alternatively, predetermined) angle from each other in the circumferential direction with respect to the outlet 250. Therefore, the process fluid may flow to the outlet 250 through the drain grooves 260.

The drain grooves 260 may not overlap the first inlet 210 or the second inlet 220 in a plan view. The drain grooves 260 may not overlap the lift holes 240 in a plan view.

The substrate processing apparatus 1C may further include a plurality of holding pins 280 disposed at the edge of the spin chuck 20C. The holding pins 280 may be spaced apart from each other in the circumferential direction along the edge of the spin chuck 20C. The holding pins 280 may come into contact with an edge of the substrate loaded on the spin chuck 20C. Therefore, the holding pins 280 may hold the substrate loaded on the spin chuck 20C. In addition, the holding pins 280 can prevent the substrate rotated by the spin chuck 20C from being detached by the centrifugal force, or reduce or minimize the likelihood of such detachment.

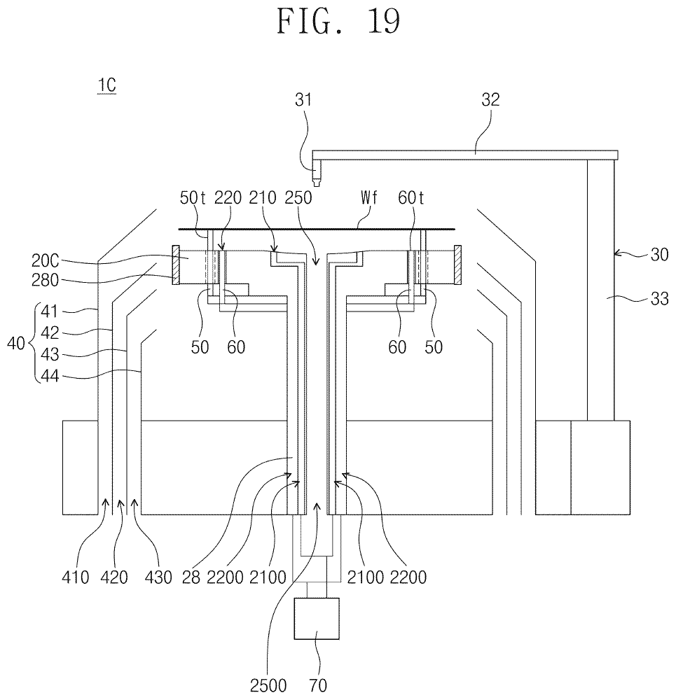

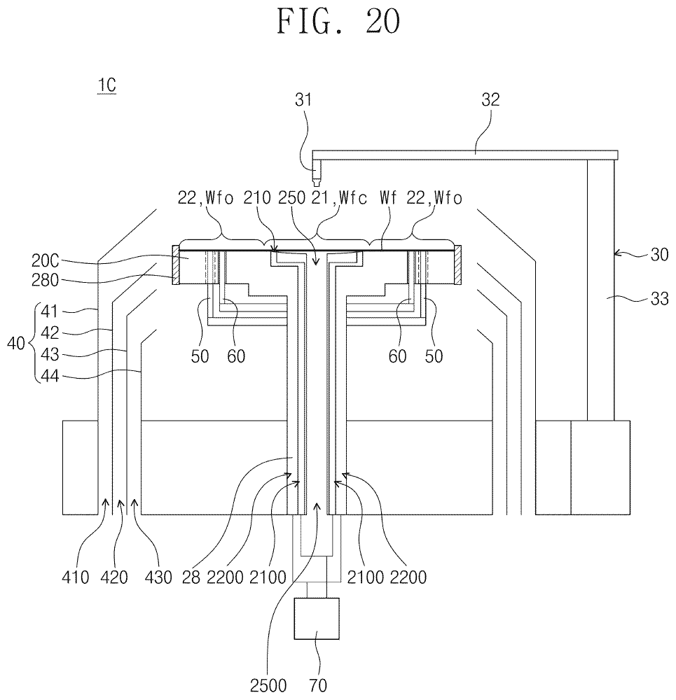

FIGS. 19 to 21 are views showing an operation method of the substrate processing apparatus of the present inventive concepts. The operation methods shown in FIGS. 19 to 21 may be implemented based on operation of the substrate processing apparatus 1C, which may further be implemented based on operation of a controller 80 to control one or more portions of the substrate processing apparatus 1C. For example, the operation methods shown in FIGS. 19 to 21 may be implemented based a processor of the controller 80 executing a program of instructions stored in a memory of the controller 80 to control one or more portions of the substrate processing apparatus 1C.

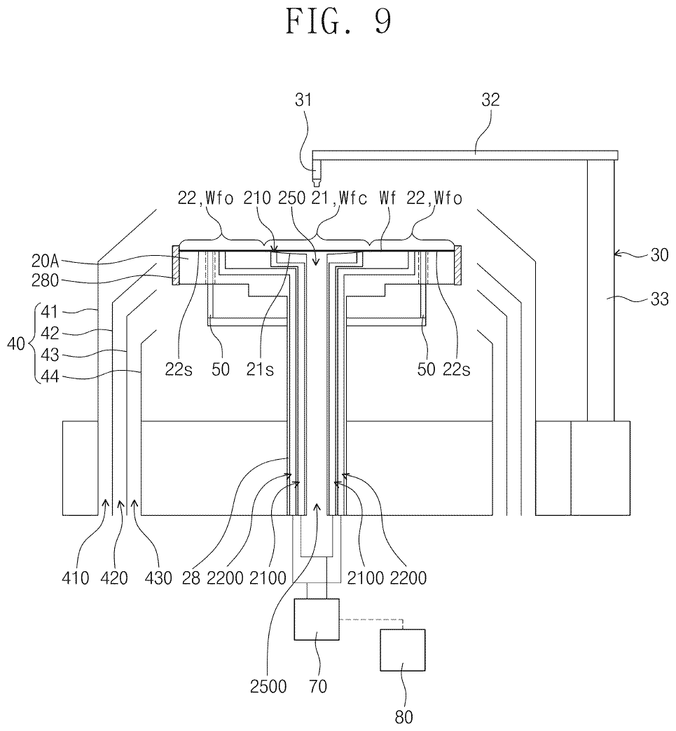

Referring to FIGS. 7, 19, and 20, similarly to FIGS. 8 and 9, the substrate Wf may be loaded onto the spin chuck 20C. Specifically, the lift pins 50 (e.g., the tips 50t thereof) may protrude from the upper surface 20Cs of the spin chuck 20C through the lift holes 240 and lift the substrate Wf transported by an arm. As the raised lift pins 50 descend again, the lifted substrate Wf may gradually descend. When the lift pins 50 (e.g., the tips 50t thereof) are inserted into the spin chuck 20C, the substrate Wf may be loaded onto the spin chuck 20C.

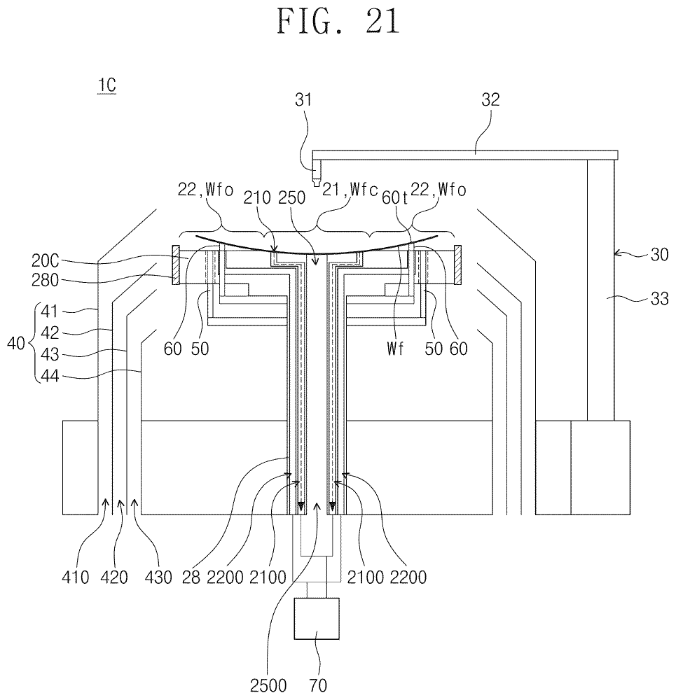

Referring to FIG. 21, a first negative pressure may be applied to the substrate Wf (e.g., the central portion Wfc thereof) to deform at least a portion of the substrate Wf into a concave shape. When the negative pressure generator 70 operates, the first negative pressure may be applied to the first inlet 210 through the first inlet passage 2100. Accordingly, the first negative pressure may be applied to the bottom surface Wfb of the loaded substrate Wf (e.g., the central portion Wfc thereof). The bottom surface Wfb of the substrate Wf (e.g., the central portion Wfc thereof) may come into close contact with the first inlet 210 by the first negative pressure. The substrate Wf (e.g., the central portion Wfc thereof) may come into close contact with the recess portion 21 (e.g., the upper surface 21s thereof) in which the first inlet 210 is located. Accordingly, the substrate Wf may be concavely deformed according to a shape of the recess portion 21 (e.g., according to a shape defined by the upper surface 21s) and may be fixed by the first inlet 210 (e.g., may be affixed to the upper surface 21s).

The operation method may further include supporting the substrate Wf. In some example embodiments, the supporting of the substrate Wf may be performed after the applying of the first negative pressure to the substrate to deform at least a portion of the substrate into the concave shape (S200). In some example embodiments, the supporting of the substrate Wf may be performed in real time during the applying of the first negative pressure to the substrate Wf to deform at least a portion of the substrate into the concave shape (S200).

The supporting of the substrate Wf may include lifting the support pins 60 (e.g., the tips 60t thereof) from the upper surface 20Cs of the spin chuck 20C. The raised support pins 60 may support the bottom surface Wfb of the concavely deformed substrate Wf (e.g., the outer portion Wfo thereof). Specifically, when the first negative pressure is applied (e.g., concurrently with the first negative pressure being applied), the substrate Wf (e.g., the central portion Wfc thereof) may come into close contact with the recess portion 21 (e.g., the upper surface 21s thereof) and may be spaced apart from the flat portion 22 (e.g., at least the outer portion Wfo may be so spaced apart). Accordingly, the substrate processing apparatus 1C may be configured to control the support pins 60 to support the substrate Wf loaded on the spin chuck 20C (e.g., at least the outer portion Wfo thereof) based on the first negative pressure being provided through one or more first inlets 210. In this case, the raised support pins 60 may support the bottom surface Wfb of the substrate Wf (e.g., at least the outer portion Wfo thereof) that is spaced apart from the flat portion 22. Accordingly, the shape maintenance strength of the concavely deformed substrate Wf can be increased.

The supplying of the process fluid onto the substrate (S300) and the rotating of the substrate (S400) may be performed after the supporting of the substrate Wf.

In the operation method of the substrate processing apparatus according to some example embodiments of the present inventive concepts, at least one among the stopping of the rotation of the substrate (S500) or the applying of a second negative pressure to the substrate to fix the substrate may be omitted.

The operation method may further include stopping the support of the substrate Wf. The stopping of the support of the substrate Wf may include descending the support pins 60. The descending support pins 60 (e.g., the tips 60t thereof) may be inserted into the spin chuck 20C. When the application of the first negative pressure is stopped and the support of the substrate Wf is stopped, the concavely deformed substrate Wf may be deformed into a flat shape.

In some example embodiments, the stopping of the support of the substrate Wf may be performed before or after the stopping of the application of the first negative pressure (S600). In some example embodiments, the stopping of the support of the substrate Wf may be performed in real time during the stopping of the application of the first negative pressure (S600).

In some example embodiments, the stopping of the support of the substrate Wf and the stopping of the application of the first negative pressure (S600) may be performed in real time during the rotating of the substrate (S400). In this case, the substrate Wf may be deformed from a concave shape to a flat shape while rotating.

FIG. 22 shows a perspective view showing a spin chuck 20D according to some example embodiments of the present inventive concepts.

Referring to FIG. 22, the spin chuck 20D may include a recess portion 21, a flat portion 22, a first inlet 210, a second inlet 220, an outlet 250, drain grooves 260, and lift holes 240 that are the same or substantially the same as the recess portion 21, the flat portion 22, the first inlet 210, the second inlet 220, the outlet 250, the drain grooves 260, and the lift holes 240 of FIGS. 1 to 4. In addition, the spin chuck 20D may include support holes 270 that are substantially the same as the support holes 270 of FIGS. 17 and 18.

The support holes 270 and the second inlets 220 may be provided in the flat portion 22 (e.g., the upper surface 22s thereof). The support holes 270 and the second inlets 220 may be alternately arranged at a particular (or, alternatively, predetermined) angle in a circumferential direction. The support holes 270 and the second inlets 220 may be spaced apart from each other.

Accordingly, the substrate processing apparatus may include the negative pressure generator 70 that applies the second negative pressure through the second inlets 220 and the support pins 60. Applying the second negative pressure to the substrate Wf through the second inlets 220 and operating the support pins 60 to support the substrate Wf may operate asynchronously. However, applying the first negative pressure to the substrate Wf through the first inlet 210 and operating the support pins 60 to support the substrate Wf may operate synchronously.

As described herein, any devices, systems, modules, portions, units, controllers, circuits, and/or portions thereof according to any of the example embodiments, and/or any portions thereof (including, without limitation, the substrate processing apparatus 1A, controller 80, substrate processing apparatus 1C, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

A substrate processing apparatus according to some example embodiments of the present inventive concepts may concavely deform a substrate loaded on a spin chuck due to a first inlet provided in an upper surface of a recess portion that is lower than an upper surface of a flat portion and a negative pressure generator providing negative pressure inside the first inlet. Therefore, a process fluid supplied from a process fluid supplier can remain in the substrate. Accordingly, the process fluid can selectively etch an upper surface of the substrate. In addition, the process fluid may not etch an edge of the substrate.

Furthermore, the substrate processing apparatus according to some example embodiments of the present inventive concepts may maintain a constant curvature of a concavely deformed substrate due to the recess portion having a concave upper surface. In addition, the stress applied to the deformed substrate can be relieved.

Moreover, the substrate processing apparatus according to some example embodiments of the present inventive concepts may flatly deform a substrate loaded on the spin chuck due to a second inlet provided in the flat upper surface of the flat portion and the negative pressure generator providing negative pressure inside the second inlet. Therefore, the process fluid supplied from the process fluid supplier can flow toward the edge of the substrate. Accordingly, the process fluid can etch the upper surface and the edge of the substrate together. In addition, the process fluid can flow along the edge to a bottom surface of the substrate and etch the bottom surface of the substrate.

In addition, the substrate processing apparatus according to some example embodiments of the present inventive concepts can improve the deformation strength and the shape maintenance strength of the substrate due to a plurality of vertically movable support pins. That is, since the plurality of support pins support the edges of the concavely deformed substrate, a shape of the deformed substrate can be maintained.

In addition, the substrate processing apparatus according to some example embodiments of the present inventive concepts can discharge process fluid between the bottom surface of the substrate and the spin chuck due to an outlet provided in a central portion of the upper surface of the recess portion.

Moreover, the substrate processing apparatus according to some example embodiments of the present inventive concepts can improve the fluidity of the process fluid between the bottom surface of the substrate and the spin chuck due to a plurality of drain grooves provided on the upper surface of the spin chuck. In addition, the discharge of the process fluid can be facilitated.

In addition, the substrate processing apparatus according to some example embodiments of the present inventive concepts can supply process fluid onto the substrate while moving a nozzle in a horizontal direction due to the nozzle provided to be movable in the horizontal direction. Accordingly, the phenomenon in which a central portion of the substrate is intensively etched can be reduced.

The above-described contents are specific example embodiments for implementing the present inventive concepts. In addition to the above-described example embodiments, the present inventive concepts will also include embodiments that can be simply designed around or easily changed. In addition, the present inventive concepts will also include technologies that can be implemented by being easily modified using some example embodiments. Therefore, the scope of the present inventive concepts should not be limited to the above-described example embodiments, but should be defined by the appended claims and their equivalents.

What is claimed is:

1. A substrate processing apparatus, comprising:
a spin chuck including a flat portion having a flat upper surface and a recess portion surrounded by the flat portion in a plan view, the recess portion having a recess upper surface, the spin chuck including a first inlet in the recess upper surface of the recess portion, the recess upper surface of the recess portion at a lower level than the flat upper surface of the flat portion;
a process fluid supplier configured to supply a process fluid onto a substrate loaded on the spin chuck; and
a negative pressure generator configured to provide a first negative pressure through the first inlet in the recess upper surface of the recess portion.

2. The substrate processing apparatus of claim 1, wherein
a level of the recess upper surface of the recess portion decreases toward a center of the spin chuck.

3. The substrate processing apparatus of claim 2, wherein
the recess upper surface of the recess portion is concave.

4. The substrate processing apparatus of claim 2, wherein
the recess upper surface of the recess portion is defined as a sloped surface inclined downward toward the center of the spin chuck.

5. The substrate processing apparatus of claim 1, wherein
the spin chuck includes a second inlet in the flat upper surface of the flat portion, and
the negative pressure generator is further configured to provide a second negative pressure through the second inlet in the flat upper surface of the flat portion.

6. The substrate processing apparatus of claim 1, further comprising:
support pins configured to at least partially extend through separate, respective support holes defined in the flat portion,
wherein the support pins are vertically movable.

7. The substrate processing apparatus of claim 1, wherein
the spin chuck has an outlet in a central portion of the recess upper surface of the recess portion.

8. The substrate processing apparatus of claim 7, wherein
the spin chuck includes a plurality of drain grooves extending from the outlet toward an edge of the spin chuck and recessed from an upper surface of the spin chuck.

9. The substrate processing apparatus of claim 1, wherein
the spin chuck includes a plurality of first inlets in the recess upper surface of the recess portion, the plurality of first inlets arranged in a circumferential direction at the upper surface of the recess portion, the plurality of first inlets including the first inlet.

10. The substrate processing apparatus of claim 1, further comprising:
lift pins configured to at least partially extend through separate, respective lift holes defined in an upper surface of the spin chuck,
wherein the lift pins are vertically movable.

11. The substrate processing apparatus of claim 1, wherein
the process fluid includes an etchant that is configured to etch the substrate loaded on the spin chuck.

12. The substrate processing apparatus of claim 1, wherein
the negative pressure generator includes a vacuum pump, the vacuum pump configured to draw fluid through the first inlet.

13. The substrate processing apparatus of claim 1, wherein
the process fluid supplier includes a nozzle over the spin chuck, the nozzle configured to discharge the process fluid, and
the nozzle is movable in a horizontal direction, the horizontal direction parallel to the flat upper surface of the flat portion.

14. A substrate processing apparatus, comprising:
a spin chuck including a flat portion having a flat upper surface and a recess portion surrounded by the flat portion in a plan view, the recess portion having a recess upper surface, the spin chuck including a first inlet in the recess upper surface of the recess portion, the spin chuck including a second inlet in the flat upper surface of the flat portion, a level of the recess upper surface of the recess portion decreasing toward a center of the spin chuck;
a process fluid supplier configured to supply an etchant onto a substrate loaded on the spin chuck; and
a negative pressure generator configured to
provide a first negative pressure through the first inlet in the recess upper surface of the recess portion, and provide a second negative pressure through the second inlet in the flat upper surface of the flat portion.

15. The substrate processing apparatus of claim 14, wherein
the negative pressure generator includes
a first negative pressure generator configured to provide the first negative pressure through the first inlet, and
a second negative pressure generator configured to provide the second negative pressure through the second inlet, and
the first negative pressure generator and the second negative pressure generator are configured to operate independently.

16. The substrate processing apparatus of claim 15, wherein
the first negative pressure generator is configured to operate asynchronously with the second negative pressure generator.

17. A substrate processing apparatus, comprising:
a spin chuck including a flat portion having a flat upper surface and a recess portion surrounded by the flat portion in a plan view, the recess portion having a recess upper surface, the spin chuck including a first inlet in the recess upper surface of the recess portion, a level of the recess upper surface of the recess portion decreasing toward a center of the spin chuck;
a process fluid supplier configured to supply an etchant onto a substrate loaded on the spin chuck;
a negative pressure generator configured to provide a first negative pressure through the first inlet in the recess upper surface of the recess portion; and
support pins configured to at least partially extend through separate, respective support holes defined in the flat portion,
wherein the support pins are vertically movable.

18. The substrate processing apparatus of claim 17, wherein
the spin chuck includes a second inlet in the flat upper surface of the flat portion, and
the negative pressure generator is further configured to provide a second negative pressure through the second inlet in the flat upper surface of the flat portion.

19. The substrate processing apparatus of claim 17, further comprising:
a plurality of lift pins configured to rise based on passing through an upper surface of the spin chuck to lift the substrate,
wherein the spin chuck includes a plurality of lift holes in the upper surface of the spin chuck, the spin chuck configured to allow the lift pins to extend at least partially through separate, respective lift holes of the plurality of lift holes.

20. The substrate processing apparatus of claim 17, wherein,
the substrate processing apparatus is configured to control the support pins to support the substrate loaded on the spin chuck based on the first negative pressure being provided through the first inlet.
